(19) United States
(12) Patent Application Publication
(10) Pub. No.: US 2014/0083508 A1
(43) Pub. Date: Mar. 27, 2014

(54) METHOD FOR FORMING AN ALUMINUM ORGANIC PHOTOVOLTAIC CELL ELECTRODE AND ELECTRICALLY CONDUCTING PRODUCT THEREOF

(71) Applicant: Research Foundation of the City University of New York, New York, NY (US)

(72) Inventors: Luat T. Vuong, Brooklyn, NY (US); Howard Rose, Malverne, NY (US); Faizullah Mashriqi, Fresh Meadows, NY (US); Rafael Betancur, Castelldefels (ES)

(21) Appl. No.: 14/036,258

(22) Filed: Sep. 25, 2013

Related U.S. Application Data
(60) Provisional application No. 61/705,245, filed on Sep. 25, 2012.

(51) Int. Cl. H01L 51/44

(52) U.S. Cl. CPC H01L 51/441
USPC 136/263; 438/82

(57) ABSTRACT

An organic photovoltaic cell is disclosed that uses an aluminum substrate with a polymeric layer overcoat. A layer of titania nanoparticles is mechanically embedded with a top surface of the aluminum substrate to provide a TiO₂ electron transporting layer (TETL) between the polymeric layer overcoat and the aluminum substrate.

### CROSS-REFERENCE TO RELATED APPLICATIONS

This application claims priority to U.S. provisional patent application No. 61/705,245 (filed Sep. 25, 2012) the entirety of which is incorporated herein by reference.

### BACKGROUND OF THE INVENTION

The subject matter disclosed herein relates to electrical devices and, in one embodiment, organic photovoltaic cells. The larger demand for inexpensive solar harvesting with a low carbon footprint stems from increasing concerns of climate change. A primary challenge facing the photovoltaics (PVs) industry is creating an efficient and affordable alternative for electricity production at a large scale. By 2020, the installed global solar capacity will be 20-40 times larger than that in 2008, which may reduce 125 to 250 megatons of carbon dioxide. Indeed, PVs produce cleaner energy, but, companies building solar harvesting equipment must reduce the manufacturing cost and the use of toxic metals. Moreover, companies need to manufacture photovoltaic cells (PVCs) with a low carbon footprint. For decades, PVCs have been used on various devices, such as, calculators and satellites. The industry, however, is not prepared for large scale manufacturing, because current PVCs use expensive materials and fabrication techniques.

Like conventional PVCs, organic PVCs convert photonic energy into electrical energy, by generating free charges which migrate to an electrode under illumination. A PVC has a semitransparent, conducting electrode into which solar photons enter. The reverse electrode is ideally a perfect conductor that acts as an ideal mirror with unit reflectivity. Between the electrodes, an active layer composed of an organic material absorbs photons to produce an exciton. These excitons migrate to a charge separation layer, where charges are formed and then transferred to an electrode. Current PVC technology self-limit its efficiency; for example, excitons often recombine before reaching a charge separation layer. Different designs for cavities and bulk heterojunction (BHJ) PVCs have been tested to reduce exciton recombination. Another limiting factor lies within the top electrode.

While attempts have been made to produce inexpensive solar cells on a large scale, none have proven entirely satisfactory. There is therefore a need to provide improved electrical devices that address at least some of these shortcomings. The discussion above is merely provided for general background information and is not intended to be used as an aid in determining the scope of the claimed subject matter.

### BRIEF DESCRIPTION OF THE INVENTION

Organic solar cells were fabricated using a combination of economic methods and materials that demonstrate the potential of inexpensive large scale production. Aluminum served as a bottom electrode, in lieu of a silver or gold electrode. Unlike conventional solar cells that use costly vacuum preparation or heat intensive techniques, the remaining layers were deposited by processing a solution on top of the aluminum. These solar cells were assembled in ambient air, to avoid using a vacuum system. A common problem with using aluminum includes the low electrical conductivity on the surface due to an aluminum oxide layer. To reduce the influence of the aluminum oxide, titanium oxide nanospheres were embedded in the aluminum. The nanospheres act as an electron conductor. Solar cells with the titanium oxide nanospheres demonstrate a four-fold increase of charge transportation in the light and a twenty fold increase of charge transportation in the dark. An advantage that may be realized in the practice of some disclosed embodiments is the production of a low electrical conductivity at the aluminum surface, which makes an enhanced and more robust solar cell.

In a first exemplary embodiment, an organic photovoltaic cell is disclosed that comprises an aluminum substrate with a layer of titania nanoparticles embedded therein. The nanoparticles have a diameter of less than about fifty nanometers, the layer of titania nanoparticles being disposed on a top surface of the aluminum substrate. A first polymer layer disposed on the aluminum substrate such that it contacts the titania nanoparticles. A second polymer layer disposed on the first polymer layer. A layer of metal nanowires disposed above the first polymer layer and in contact with the second polymer layer.

In a second exemplary embodiment, a method for forming an electrical device using solution processing is disclosed. The method comprises coating a top surface of an aluminum substrate with a suspension of titania nanoparticles in a liquid, wherein the titania nanoparticles have an average diameter of less than about fifty nanometers. The liquid is permitted to evaporate to leave a layer of the titania nanoparticles on the top surface. The titania nanoparticles are pressed into the top surface while maintaining the aluminum substrate at a temperature below about eighty degrees centigrade.

In a third exemplary embodiment, a titania embedded aluminum substrate is disclosed. The titania embedded aluminum substrate is formed by a method that comprises coating a top surface of an aluminum substrate with a suspension of titania nanoparticles in a liquid directly after a portion of the top surface is removed to expose a fresh surface. The titania nanoparticles have an average diameter of less than about fifty nanometers. The liquid is permitted to evaporate to leave a layer of the titania nanoparticles on the top surface. The titania nanoparticles are pressed into the top surface while maintaining the aluminum substrate at a temperature below about eighty degrees centigrade.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIG. 1 is a cross-sectional view of a exemplary photovoltaic cell;

FIG. 2 is a flow diagram depicting an exemplary process for forming a photovoltaic cell;

FIG. 3 illustrates alumina thickness as a function of time both with and without titania treatment;

FIG. 4 depicts film thickness as a function of applied pressure both with and without titania treatment; and

FIG. 5 shows a calculated refractive index of the alumina and titania as a function of applied pressure.

### DETAILED DESCRIPTION OF THE INVENTION

Although aluminum is the third most abundant metal on Earth, very few groups have attempted to use aluminum as a substrate in a PVC and others have shown that PVCs with aluminum electrodes degrade and cease to function within a day of fabrication. However, compared to other metal substrates, such as silver, gold, or platinum, that have been previously used, using an aluminum substrate would substantially decrease the price per PVC module. Employing an aluminum substrate has unique advantages. Aluminum has both a low work function and high reflectivity. Metal substrates, which retard water and oxygen diffusion, can be shaped to enhance light trapping. An aluminum substrate makes panel installation achievable and more convenient. Moreover, it retains the low-cost throughput advantages of roll-to-roll deposition for large scale production.

Unfortunately, in air, pure aluminum grows an Al₂O₃ layer. This layer grows logarithmically, and almost instantaneously, for example, 4 nm grow in 100 ps. Although, the Al₂O₃ layer protects the aluminum from further oxidation, Al₂O₃ is not desired in PVCs. Al₂O₃ causes lower emissivity in the high frequency area, as well as decreased reflectivity. Conventional PVCs with an aluminum cathode often suffer from accelerated degradation in air due to decreased electron transport across the insulting Al₂O₃ coating. As this charge-blocking layer grows, PVC efficiency drastically decreases. Thus, it becomes imperative to alter the surface of the aluminum substrate to make charge injection and extraction possible at the cathode interface. Without wishing to be bound to any particular theory, Applicant believes Al₂O₃ has a cylindrical porous geometry within which semiconductive metal oxides (e.g. CrOₓ or TiO₂) may be embedded. The resulting composite structure decreases or even eliminates the insulation caused by Al₂O₃ at the cathode surface.

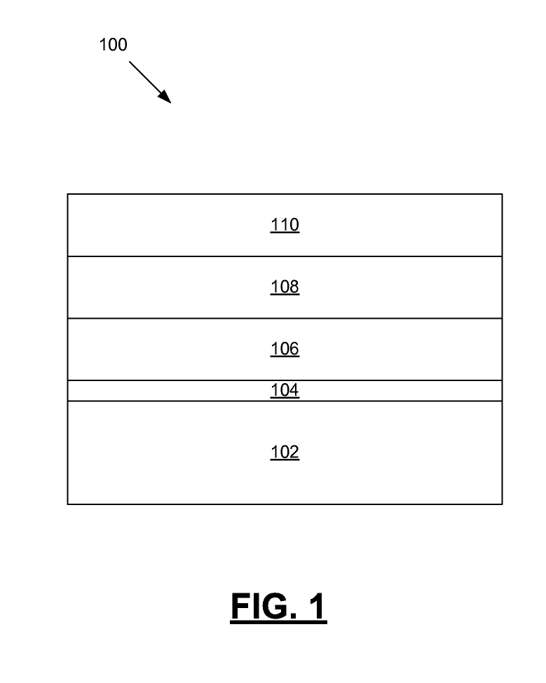

As shown in FIG. 1, a fully solution-processed organic photovoltaic cell 100 with an aluminum substrate 102 addresses production and preparation cost issues, towards making solar energy harvesting economically feasible. Moreover, the solution processing of all the layers increases the potential of roll-to-roll production. The layer is thermodynamically robust and functions over weeks, unlike sputtered aluminum cells that fail within a day. In the exemplary embodiment of FIG. 1, the aluminum substrate 102 serves as an opaque bottom cathode. In one embodiment, the substrate is a planar surface. In another embodiment, the substrate is a wire. A layer of titania nanoparticles 104 is mechanically embedded in the top surface of the aluminum substrate 102 such that the nanoparticles are dispersed in the top surface to provide a TiO₂ electron transporting layer (TETL). A first polymer layer 106 may be an organic electron acceptor layer composed of, for example, P3HT:PCBM bulk heterojunction (poly(3-hexylthiophene):phenyl-C61-butyric acid methyl ester). The TETL electrically connects the first polymer layer 106 to the aluminum substrate 102. After the first polymer layer 106 is deposited onto the aluminum substrate 102, the deposition of a second polymer layer 108 is performed. The second polymer layer may be an electron donor (e.g. PEDOT:PSS (poly(3,4-ethylenedioxythiophene):poly(4-styrenesulfonate). A layer of metal nanowires 110 (e.g. silver nanowires) are placed above the polymer layers.

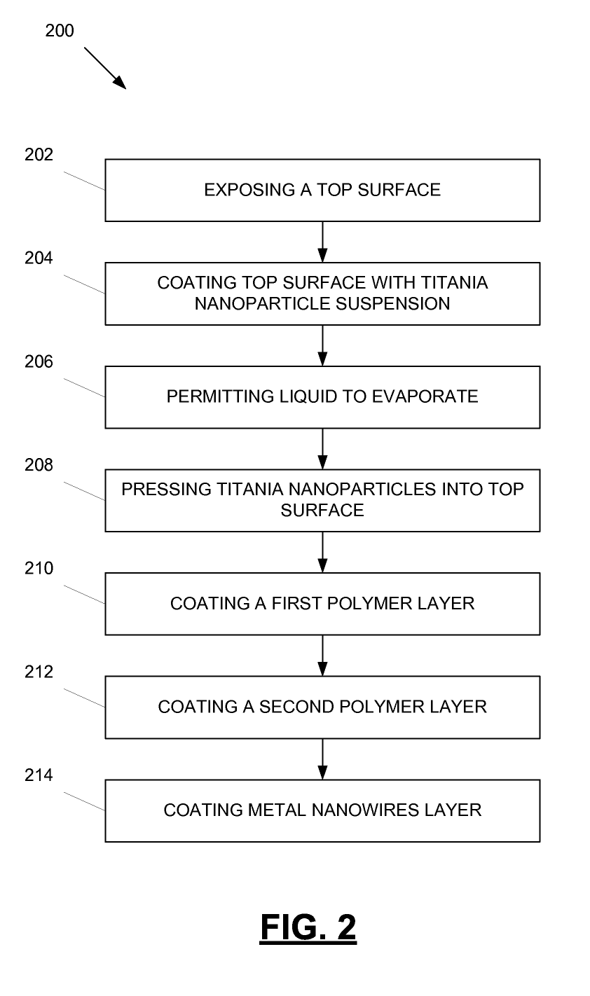

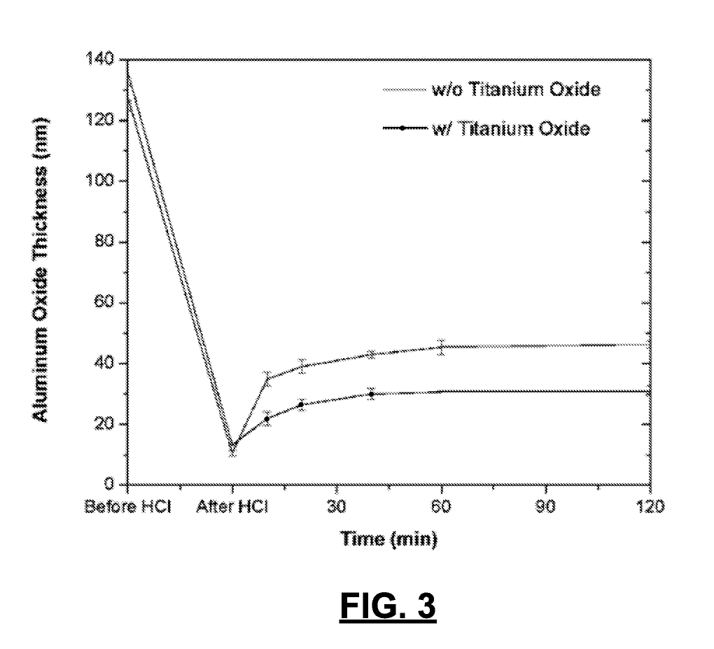

FIG. 2 depicts an exemplary method 200 for forming an organic photovoltaic cell. The method 200 may be executed using solution-based processing techniques including roll-to-roll deposition. In one embodiment, the method is executed under ambient conditions (e.g. near room temperature and atmospheric pressure while exposed to air). The method 200 begins within step 202, wherein at least a portion of a top surface of alumina is removed from an aluminum substrate to expose a top surface. In one embodiment, the portion of the top surface may be removed mechanically. For example, the aluminum substrate may be sequentially sanded with 30 micrometer, 15 micrometer, 9 micrometer, 3 micrometer, 2 micrometer and 1 micrometer polishing paper. Randomly-orientated grating structures resulted from the sanding grit. In another embodiment, the portion of the top surface may be removed chemically. For example, the aluminum substrate may be placed in an acid, such as hydrochloric acid. In one embodiment, both mechanical and chemical treatments are sequentially used. In one such sequential treatment, a 10 nm thick layer of aluminia resulted(as determined by ellipsometery). This layer grew to 50 nm within two hours if untreated with titania. See FIG. 3. When the surface is treated with titania (see steps 204-208), the thickness is only 30 nm, showing the titania treatment inhibits alumina formation.

In step 204, the top surface was coated with a suspension of titania nanoparticles in a liquid before the aluminia layer grew. In one embodiment a 10% wt aqueous suspension of titania nanoparticles with average diameters less than 50 nm was coated on the aluminum substrate by pressing the aluminum substrate surface with a glass slide. The suspension may be spin-coated, dip-coated, or applied using other, similar techniques. In one embodiment, the titania nanoparticles are sputtered. In another embodiment, titania nanoparticles are dissolved in a liquid medium to product a homogenous solution. Such an approach minimizes the formation of localized clusters.

In step 206, the liquid is permitted to evaporate to leave a layer of the titania nanoparticles on the top surface. In one embodiment, heat is applied to facilitate the evaporation process and open pores within the aluminum substrate. For example, the aluminum substrate may be increased in temperature above the boiling point of the liquid (e.g. above 100° C. for water).

In step 208, after the liquid has evaporated, the titania nanoparticles are pressed into the top surface while maintaining the aluminum substrate at room temperature. Exemplary pressures include 1000 psi (6.9 MPa) and 2000 psi (13.8 MPa) which may be delivered from a shop press. In one embodiment, a pressure between 3000 psi (20.7 MPa) and 5000 psi (34.5 MPa). In one embodiment, the temperature is maintained below about 80° C. In one embodiment, the temperature is maintained below about 50° C. In another embodiment, the temperature is maintained between about 20° C. and about 30° C. The resulting composite includes the titania nanoparticles embedded within pores of the Al₂O₃ top surface. In one embodiment, steps 204, 206 and 208 are performed under an inert gas atmosphere (e.g. argon).

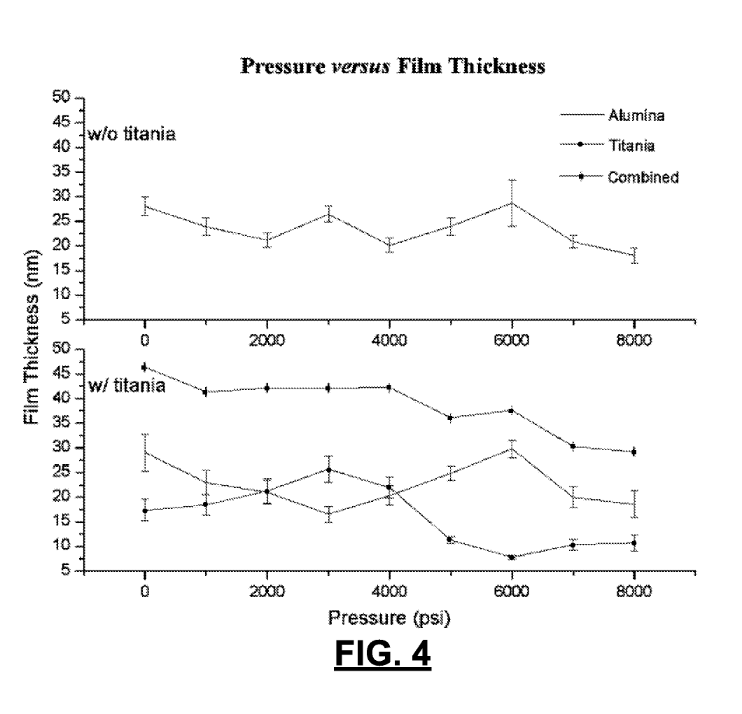

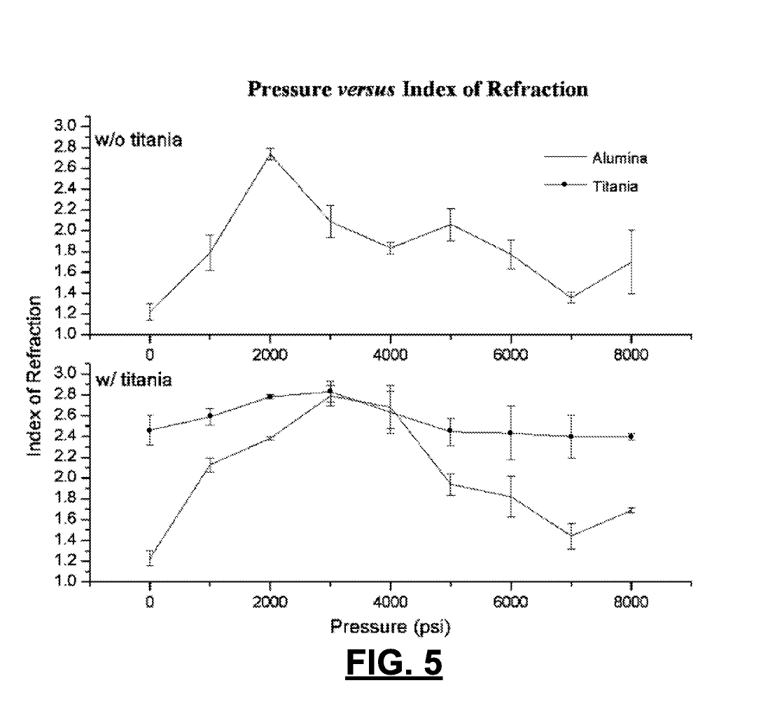

FIG. 4 shows the measured thicknesses of the alumina and titania for the layers as a function of pressure treatment. All measurements are taken within the hour of treatment. The discrepancies arise due to surface roughness in the samples. In the top figure, which lacks titania, pressure does not change the thickness of alumina, which is approximately 25-30 nm In the bottom figure, which includes titania, there is a cross-over regime between 2000-4000 psi where the titania and alumina is “indistinguishable” and may a more conducting material. FIG. 5 shows a calculated refractive index of the alumina and titania. In the intermediate regime of interest (between 3000 and 4000 psi) the refractive index of titania and alumina is indistinguishable. This is the regime where the resistivity is the lowest, as well. This data points to there being an important pressure for titania and alumina to mix and form a more conducting coating than alumina alone.

In step 210, a first polymer in a first liquid medium is coated on the aluminum substrate. The first liquid medium is permitted to evaporate to form a first polymer layer such that the first polymer layer contacts the titania nanoparticles. For example, a 1:1 P3HT:PCBM blend may be dissolved in o-dichlorobenzene to a final concentration of 2.5 wt % and thereafter deposited onto an aluminum substrate via a monolayer deposition using a meniscus syringe pump at 2 ml per minute. The blend was allowed to dry in a covered petri dish and then annealed at 110° C. for 10 minutes to evaporate any remaining solvent.

In step 212, a second polymer in a second liquid medium is coated on to the first polymer layer. The second liquid medium is permitted to evaporate to form a second polymer layer such that the second polymer layer contacts the first polymer layer. For example, a PEDOT/PPS aqueous blend with 0.1% w/w ZONYL® FSO fluorosurfactant was sonicated for 15.0 minutes and then deposited at 3 ml per minute. The blend was then annealed at 120° C. for 25 minutes to evaporate any remaining water.

In step 214, metal nanowires are coated in a third liquid medium on the second polymer layer. The third liquid medium is permitted to evaporate to form a metal nanowire layer such that the metal nanowire layer contacts the second polymer layer. In one embodiment, the metal nanowires are silver nanowires. For example, a 0.05% w/w aqueous solution of silver nanowires may be drop-cast onto the second polymer layer to yield a semi-transparent film when the water evaporates. In one embodiment, silver nanowires with an average diameter of about 115 nm and a length of about 30 micrometers were used. As superstrate, a silver nanowire mesh transmits photons to the underlying organic material. As charges form in the active polymer layer, positively charged holes are relayed from the PEDOT:PPS to the silver nanowires. Since the holes are transferred from nanowire to nanowire, more welded nanowire junctions allow a hole to travel a longer distance throughout the superstrate. While this drop-casting method may limit the amount of control the user has over nanowire orientation, it does retain the low-cost throughput benefits of solution-based processing, including adaptation to roll-to-roll fabrication.

To characterize the oxidation, the Al₂O₃ thickness was measured optically via polarization dependent reflectance. These measurements were modeled with a theoretical Mueller matrix and various optical vectors which, in turn, quantify the refractive indices and the Al₂O₃ layer thickness. As described in provisional patent application 61/705,245, the content of which is incorporated by reference, the results showed an Al₂O₃ thickness of 144.70±10.92 nm.

The PVC performance was tested in ambient air. A Keithley 2611A sourcemeter was used to supply a potential difference and measure the current-density in the dark and under a solar simulator providing AM 1.5 G conditions. Using LabVIEW 2012, a software was programmed to control the sourcemeter and measure current-density versus voltage (I−V) curves. To connect the PVC and the sourcemeter, the bottom aluminum cathode was exposed by dissolving the silver nanowires and organic layers with acetone. Hard gold probes were put in contact with both the silver nanowire anode and the aluminum cathode. Ten PVCs with a TETL were fabricated using identical methods to ensure procedural variations were minimal. As a comparative example, ten PVCs that lacked a TETL were also fabricated.

PVCs without a TETL yield low short circuit current-density under illumination (J_{sc}0.5 μA/□) and in the dark (J_{sc}=0.1 μA/□). The five-fold increase in the short circuit current-density under illumination suggests that more electrons are being relayed to the cathode, which shows proper functioning of the PVC. In comparison to previous PVCs, the short circuit current-density remained low suggesting that the insulating Al₂O₃ on top of the aluminum cathode is the main mechanism causing the PVC to degrade. This PVC demonstrates both basic achievements, including the propagation of charges, and fundamental problems, including insufficient electron transport into the cathode.

PVCs with a TETL showed quadruple the short circuit current-density under illumination (J_{sc}=5.0 μA/□) and increases 20 fold in the dark (J_{sc}=2.0 μA/□). Although the short circuit current-density remains low in comparison to PVCs without solution processed layers, the large increase with the addition of the TETL suggests that more electrons are being transported from the organic layer to the aluminum cathode.

The treated aluminum substrates disclosed herein are not limited to use in photovoltaic cells. For example, one can envision transmission lines or computer components that are aluminum doped with titania to achieve lower heating/electrical losses.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. An organic photovoltaic cell comprising:
an aluminum substrate;
a layer of titania nanoparticles, each having a diameter of less than about fifty nanometers, the layer of titania nanoparticles being disposed on a top surface of the aluminum substrate;
a first polymer layer disposed on the aluminum substrate, the first polymer layer contacting the titania nanoparticles;
a second polymer layer disposed on the first polymer layer, a layer of metal nanowires disposed above the first polymer layer and in contact with the second polymer layer.

2. The organic photovoltaic cell as recited in claim 1, wherein the first polymer layer comprises an electron acceptor and the second polymer layer comprises an electron donor.

3. The organic photovoltaic cell as recited in claim 1, wherein the first polymer layer comprises poly(3-hexylthiophene):phenyl-C61-butyric acid methyl ester (P3HT:PCBM) and the second polymer layer comprises poly(3,4-ethylenedioxythiophene):poly(4-styrenesulfonate (PEDOT:PSS).

4. A method for forming an electronic device using solution processing, the method comprising:
coating a top surface of an aluminum substrate with a suspension of titania nanoparticles in a liquid, wherein the titania nanoparticles have a diameter of less than about fifty nanometers;
permitting the liquid to evaporate to leave a layer of the titania nanoparticles on the top surface;
pressing the titania nanoparticles into the top surface while maintaining the aluminum substrate at a temperature below about eighty degrees centigrade.

5. The method as recited in claim 4, further comprising removing at least a portion of the top surface from the aluminum substrate directly prior to the step of coating.

6. The method as recited in claim 4, wherein the liquid has a boiling point and the step of permitting increases the aluminum substrate to a temperature above the boiling point of the liquid.

7. The method as recited in claim 4, wherein the step of pressing applies a pressure of at least 2000 psi.

8. The method as recited in claim 4, wherein the liquid is water.

9. The method as recited in claim 4, further comprising coating a first polymer in first liquid medium on the aluminum substrate and permitting the first liquid medium to evaporate to form a first polymer layer such that the first polymer layer contacts the titania nanoparticles.

10. The method as recited in claim 9, further comprising coating a second polymer in second liquid medium on the first polymer layer and permitting the second liquid medium to evaporate to form a second polymer layer such that the second polymer layer contacts the first polymer layer.

11. The method as recited in claim 10, wherein the first polymer layer comprises an electron acceptor and the second polymer layer comprises an electron donor.

12. The method as recited in claim 10, wherein the first polymer layer comprises poly(3-hexylthiophene):phenyl-C61-butyric acid methyl ester (P3HT:PCBM) and the second polymer layer comprises poly(3,4-ethylenedioxythiophene):poly(4-styrenesulfonate (PEDOT:PSS).

13. The method as recited in claim 10, further comprising coating metal nanowires in a third liquid medium on the second polymer layer and permitting the third liquid medium to evaporate to form a metal nanowire layer such that the metal nanowire layer contacts the second polymer layer.

14. The method as recited in claim 13, wherein the metal nanowires are silver nanowires.

15. A titania-embedded aluminum substrate formed by the method as recited in claim 5.
